(19) United States
(12) Patent Application Publication
(10) Pub. No.: US 2013/0307147 A1
(43) Pub. Date: Nov. 21, 2013

(54) CHIP PACKAGE AND METHOD FOR FORMING THE SAME

(71) Applicant: XINTEC INC., Jhongli City (TW)

(72) Inventor: Chien-Hung LIU, New Taipei City (TW)

(73) Assignee: XINTEC INC., Jhongli City (TW)

(21) Appl. No.: 13/895,235

(22) Filed: May 15, 2013

Related U.S. Application Data
(60) Provisional application No. 61/649,189, filed on May 18, 2012.

(51) Int. Cl. H01L 23/498; H01L 21/78

(52) U.S. Cl. CPC H01L 23/49811; H01L 21/78
USPC 257/737; 438/460; 438/667

(57) ABSTRACT

Embodiments of the present invention provide a chip package including: a substrate having a first surface and a second surface; a device region located in the substrate; a conducting pad structure disposed on the substrate and electrically connected to the device region; a spacer layer disposed on the first surface of the substrate; a second substrate disposed on the spacer layer, wherein a cavity is created and surrounded by the second substrate, the spacer layer, and the substrate on the device region; and a through-hole extending from a surface of the second substrate towards the substrate, wherein the through-hole connects to the cavity.

### CROSS REFERENCE TO RELATED APPLICATIONS

This application claims the benefit of U.S. Provisional Application No. 61/649,189 filed on May 18, 2012, entitled “Chip package and method for forming the same,” which application is hereby incorporated herein by reference.

### BACKGROUND OF THE INVENTION

1. Field of the Invention

The invention relates to a chip package and a method for forming the same, and in particular, relates to a chip package formed by using a wafer-level packaging process.

2. Description of the Related Art

The chip package packaging process is one important step when forming electronic products. A chip package not only provides protection for the chips from environmental contaminants, but also provides a connection interface for electronic elements therein and chips packaged therein.

Because the conventional chip packaging process is complicated, a simplified chip packaging process is desired.

### BRIEF SUMMARY OF THE INVENTION

According to an illustrative embodiment of the invention, a chip package includes: a substrate having a first surface and a second surface; a device region located in the substrate; a conducting pad structure disposed on the substrate and electrically connected to the device region; a spacer layer disposed on the first surface of the substrate; a second substrate disposed on the spacer layer, wherein the second substrate, the spacer layer and the substrate surround a cavity on the device region; and a through-hole extending from a surface of the second substrate towards the substrate, wherein the through-hole connects to the cavity.

According to another illustrative embodiment of the invention, a method for forming a chip package includes: providing a substrate having a first surface and a second surface, wherein the substrate includes a device region formed therein and a conducting pad structure disposed on the substrate and electrically connected to the device region; forming a spacer layer on the first surface of the substrate; forming a second substrate on the spacer layer, wherein a cavity is created and surrounded by the second substrate, the spacer layer and the substrate on the device region; and removing a portion of the second substrate from a surface of the second substrate for forming a through-hole extending towards the substrate, wherein the through-hole connects to the cavity.

According to yet another illustrative embodiment of the invention, a method for forming a chip package includes: providing a substrate having a first surface and a second surface, wherein the substrate includes a device formed therein and a conducting pad structure disposed on the substrate and electrically connected to the device region; providing a second substrate; forming a spacer layer on the second substrate; bonding the spacer layer to the first surface of the substrate, wherein a cavity is created and surrounded by the second substrate, the spacer layer and the substrate on the device region; and removing a portion of the second substrate from a surface of the second substrate for forming a through-hole extending towards the substrate, wherein the through-hole connects to the cavity.

A detailed description is given in the following embodiments with reference to the accompanying drawings.

### BRIEF DESCRIPTION OF THE DRAWINGS

The present invention can be further understood by reading the subsequent detailed description and examples with references made to the accompanying drawings, wherein:

FIGS. 1A-1J show cross-sectional views of the formation of a chip package according to an embodiment of the present invention.

FIGS. 2A-2F show cross-sectional views of the formation of a chip package according to another embodiment of the present invention.

FIGS. 3A-3D show cross-sectional views of chip packages according to embodiments of the present invention.

### DETAILED DESCRIPTION OF THE INVENTION

The manufacturing method and method for use of the embodiment of the invention are illustrated in detail as follows. It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

A chip package according to an embodiment of the present invention may be used to package a variety of chips. For example, the chip package of the embodiments of the invention may be applied to active or passive elements, or electronic components with digital or analog circuits, such as opto electronic devices, micro electro mechanical systems (MEMS), micro fluidic systems, and physical sensors for detecting the physical quantity variation of heat, light, or pressure. Particularly, a wafer scale package (WSP) process may be applied to package semiconductor chips such as image sensor devices, light-emitting diodes (LEDs), solar cells, RF circuits, accelerators, gyroscopes, micro actuators, surface acoustic wave devices, pressure sensors, ink printer heads, or power MOSFET modules.

The wafer scale package process mentioned above mainly means that after the package process is accomplished during the wafer stage, the wafer with chips is cut to independent packages. However, in a specific embodiment, separated chips may be redistributed overlying a supporting wafer and then be packaged, which may also be referred to as a wafer scale package process. In addition, the above mentioned wafer scale package process may be also adapted to form chip packages of multi-layer integrated circuit devices by stacking a plurality of wafers having integrated circuits. In one embodiment, the diced package is a chip scale package (CSP). The size of the chip scale package (CSP) may be only slightly larger than the size of the packaged chip. For example, the size of the chip package is not larger than 120% of the size of the packaged chip.

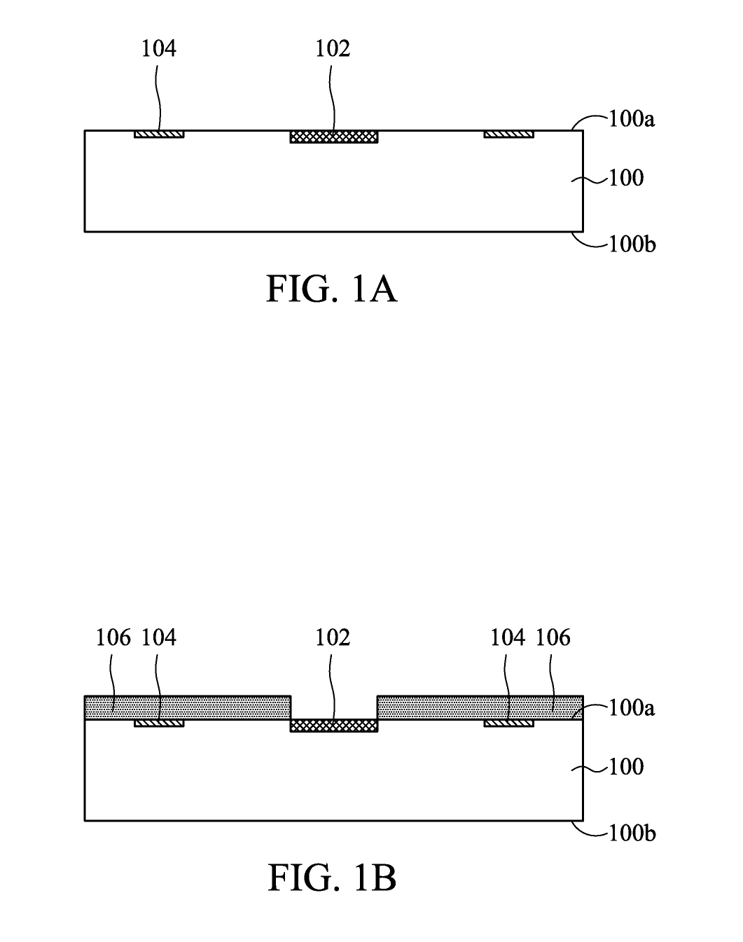

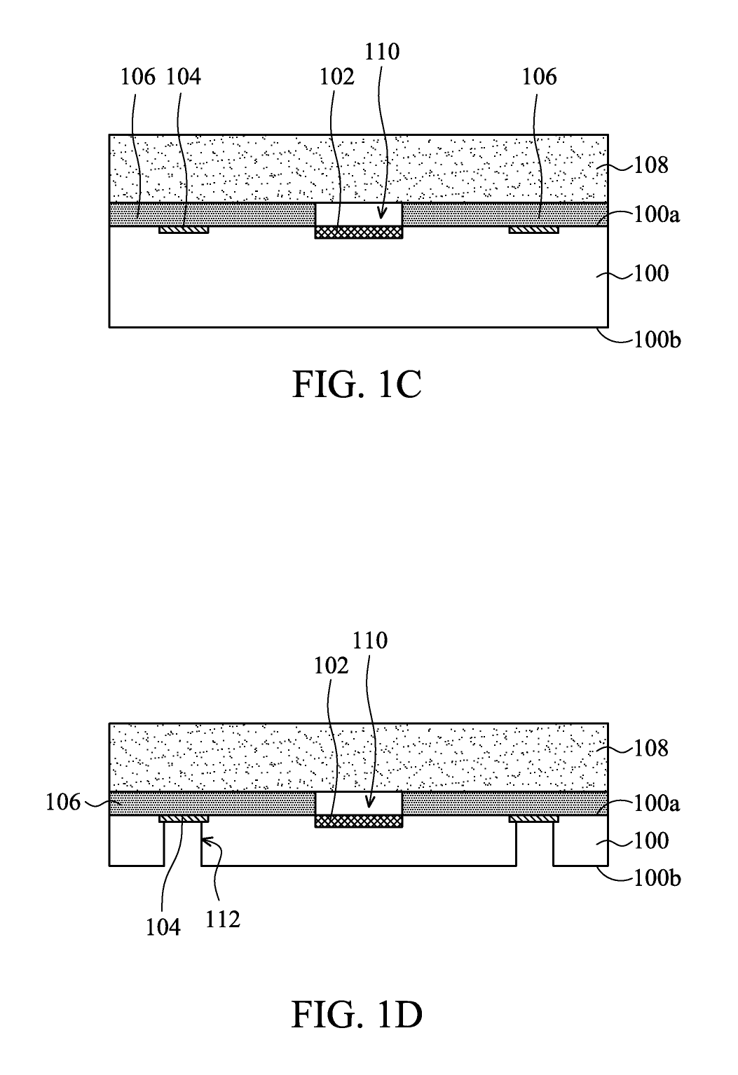

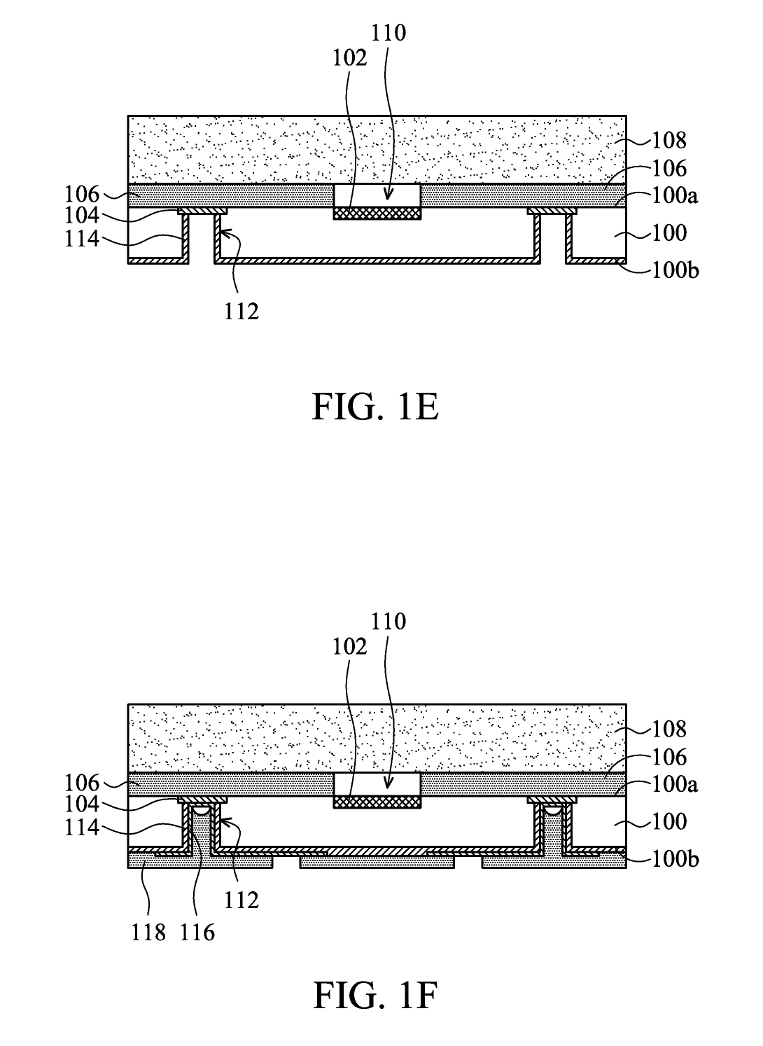

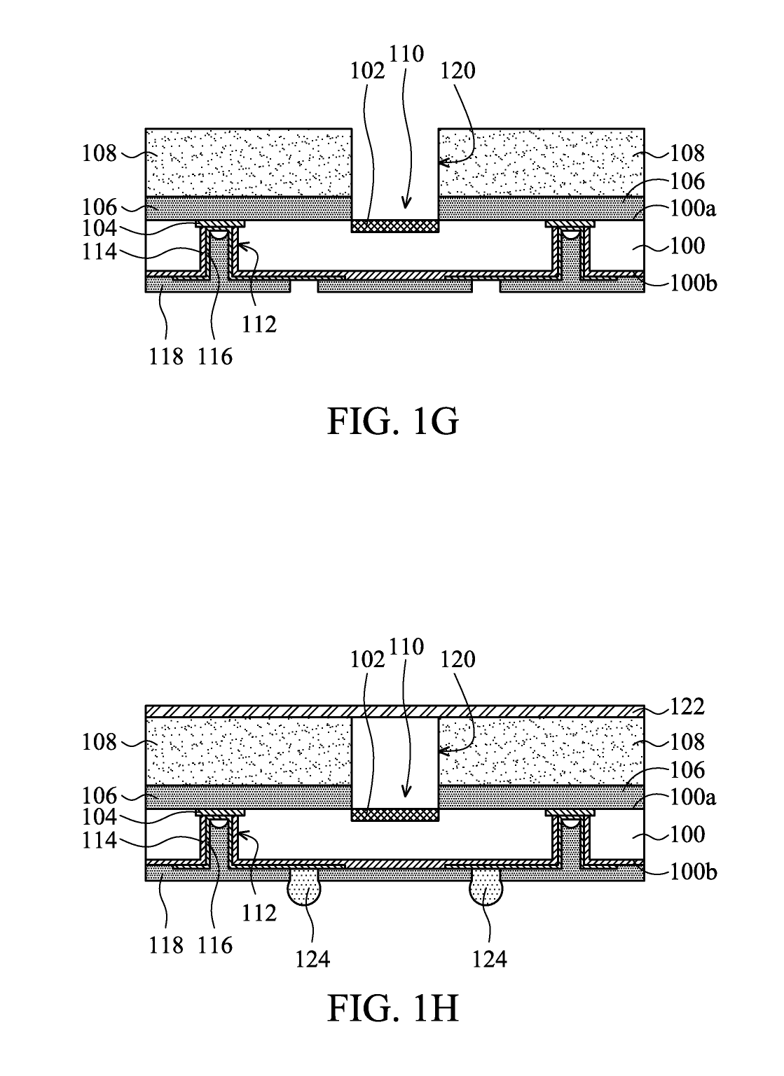

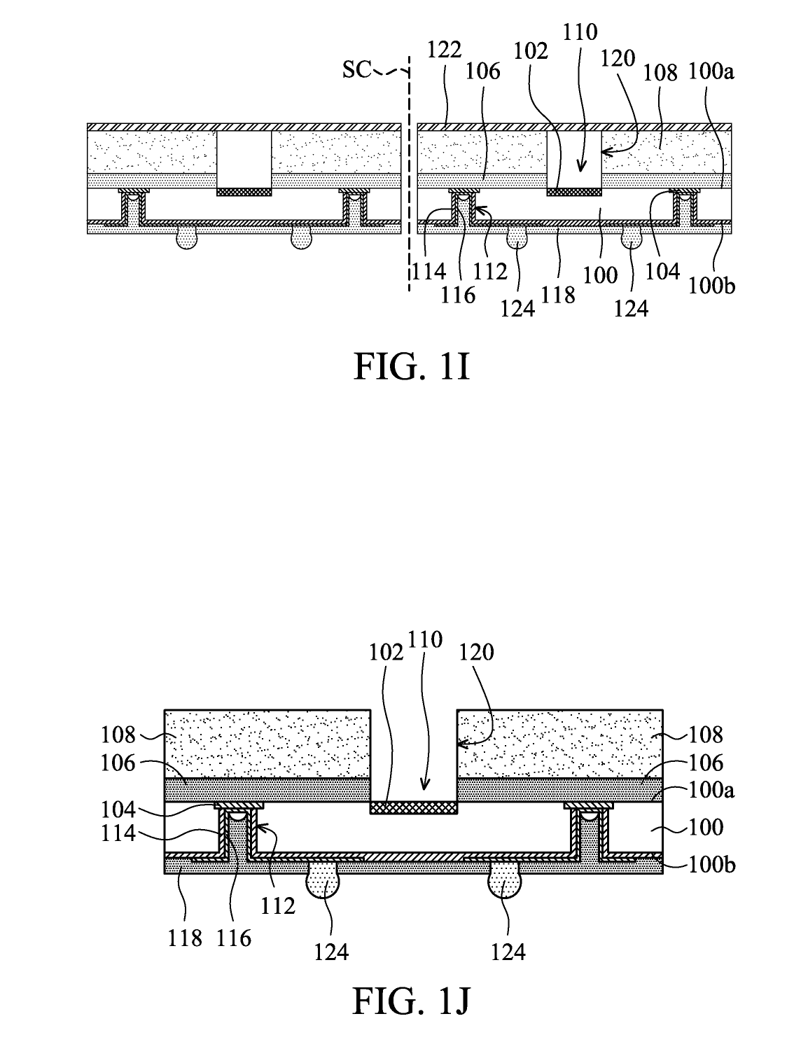

FIGS. 1A-1J show cross-sectional views of the formation of a chip package according to an embodiment of the present invention. As shown in FIG. 1A, a substrate 100 having a surface 100a and a surface 100b is provided. In an embodiment, the substrate 100 may be a semiconductor wafer, such as a silicon wafer.

In an embodiment, a device region 102 is formed in the substrate 100. The device region 102 may include, for example, but is not limited to, a temperature sensing device, a moisture sensing device, a pressure sensing device, or a combination thereof. In an embodiment, the devices in the device region 102 may be exposed at the surface 100a. The devices in the device region 102 may electrically connect to a conducting pad structure 104 on the substrate 100 via an interconnection (not shown). In an embodiment, the conducting pad structure 104 may be formed in a dielectric layer (not shown) on the substrate 100. The conducting pad structure 104 may be composed of a plurality of stacked conducting pads, one conducting pad, or a plurality of conducting pads with interconnection structures interposed therebetween.

Then, as shown in FIG. 1B, a spacer layer 106 is formed on the surface 100a of the substrate 100. In an embodiment, the spacer layer 106 comprises an epoxy resin, a silicon gel polymer, inorganic materials, or a combination thereof. In an embodiment, the spacer layer 106 comprises a photoresist material and is able to be patterned by exposure and development processes. In an embodiment, the spacer layer 106 has a substantially flat upper surface. In an embodiment, moisture is substantially not absorbed by the spacer layer 106.

As shown in FIG. 1C, a substrate 108 is then disposed on the spacer layer 106. A cavity 110 may be created by the substrate 108, the spacer layer 110 and the substrate 100, surrounding on the device region 102. The substrate 108 may be a semiconductor substrate, a metal substrate, a polymer substrate, a ceramic substrate, or a combination thereof. In an embodiment, the substrate 108 may be an opaque substrate (for visible light or infrared light). In an embodiment, the spacer layer 106 may directly contact to the substrate 108. In addition, in an embodiment, the spacer layer 106 may be adhesive itself and can bond the substrate 100 to the substrate 108. Thus, spacer layer 106 may contact none of adhesion glue, thereby assuring that the spacer layer 106 will not move due to disposition of the adhesion glue. Furthermore, since the adhesion glue is not needed, the device region 102 may not be contaminated by the overflow of the adhesion glue.

For forming conductive traces that electrically connect to the conducting pad structure 104, a through-substrate conductive structure may be optionally formed in the substrate 100. However, it should be noted that the present invention is not limited thereto. In other embodiments, other conductive traces (such as wirings) may be used for electrical connection with the conducting pad structure 104. In the following descriptions, an embodiment that comprises a through-hole conductive structure formed in the substrate 100 is illustrated.

As shown in FIG. 1D, the substrate 100 may be optionally thinned from the surface 100b of the substrate 100. For example, a mechanical polishing process, a chemical mechanical polishing process, an etching process, or a combination thereof may be performed on the surface 100b of the substrate 100 for thinning the substrate 10 to a suitable thickness.

Then, a portion of the substrate 100 may be removed from the surface 100b of the substrate 100 for forming a hole 112 that extends towards the conducting pad structure 104. In an embodiment, the hole 112 may be formed by a dry etching process, a wet etching process, a laser drill process, or a combination thereof. In an embodiment, the hole 112 may expose a portion of the conducting pad structure 104. The sidewalls of the hole 112 may be perpendicular to the surface 100b of the substrate 100. Alternatively, the sidewalls of the hole 112 may be inclined to the surface 100b of the substrate 100. In an embodiment, the opening size of the hole 112 may be gradually increased along the direction from the surface 100b to the surface 100a. When performing various processes to the substrate 100, the substrate 108 may be used as a support substrate for convenience. Thus, the substrate 100 preferably has a flat upper surface.

Then, as shown in FIG. 1E, an insulating layer 114 may be formed on the surface 100b and the sidewalls of the hole 112. The material of the insulating layer 114 may be, for example, but is not limited to, an epoxy resin, a solder mask layer, or other suitable insulating materials such as an inorganic material including a silicon oxide layer, a silicon nitride layer, a silicon oxynitride layer, metal oxides, or a combination thereof, or organic polymer materials including butylcyclobutene (BCB, Dow chemical Co.), parylene, polynaphthalenes, fluorocarbons, acrylates and so on. The method for forming the insulating layer 114 may include (but is not limited to) a coating process, such as such as spin coating, spray coating, curtain coating, or other suitable depositing processes, such as liquid phase deposition, physical vapor deposition, chemical vapor deposition, low pressure chemical vapor deposition, plasma enhanced chemical vapor deposition, rapid thermal chemical vapor deposition, or atmospheric pressure vapor deposition. In an embodiment, the formed insulating layer 114 may cover the conducting pad structure 104 underlying the bottom of the hole 112. In this case, for example, a portion of the insulating layer 114 may be removed by an etching process, thereby exposing the conductive pad structure 104.

As shown in FIG. 1F, a trace layer 116 is then formed on the insulating layer 114. The trace layer 116 may extend into the hole 112 and electrically connect to the conducting pad structure 104. The material of the trace layer 116 may be (but is not limited to) copper, aluminum, gold, platinum, nickel, tin, or a combination thereof. Alternatively, the trace layer 116 may comprise a conductive polymer material or a conductive ceramic material (e.g., indium tin oxide or indium zinc oxide). The method for forming the trace layer 116 may comprise a physical vapor deposition process, an electroplating process, a chemical plating process, or a combination thereof. In an embodiment, a seeding layer (not shown) may be formed on the surface 100b of the substrate 100 by a physical vapor deposition process. Then, a patterned masking layer (not shown) having an opening pattern corresponding to the desirable pattern of the trace layer may be formed on the seeding layer, wherein the opening pattern of the patterned masking layer exposes the underlying seeding layer. Then, a conductive material is plated on the exposed seeding layer, and then the patterned masking layer is removed. Next, an etching process is performed to remove the portion of the seeding layer which has been covered by the patterned masking layer for forming the trace layer 116 having the desirable pattern.

Then, a protective layer 118 may be optionally formed on the surface 100b of the substrate 100 and the trace layer 116. The material of the protective layer 118 may be (but is not limited to) a solder mask, polyimide, a polyimide-like material (Polyimide-like material), or a combination thereof, and the method for forming the protective layer 118 may be electroplating, spin-coating, spray coating, curtain coating, or a combination thereof. In an embodiment, the protective layer 118 comprises a photoresist material and therefore can be patterned by exposure and development processes. For example, the protective layer 118 may have openings exposing a portion of the trace layer 116, as shown in FIG. 1F.

Then, as shown in FIG. 1G, a portion of the substrate 100 may be removed from the surface 100b of the substrate 100 for the formation of a through-hole 120 which extends towards the substrate 100. The through-hole 120 may connect to the cavity 110. In an embodiment, the through-hole 120 may be then formed using a wet etching process, a dry etching process, a laser drill process, or a combination thereof. In this embodiment, the sidewalls of the through-hole 120 may be substantially coplanar with the sidewalls of the spacer layer 106. The through-hole 120 may have an opening size equal to the device region 102. In another embodiment, the through-hole may have an opening size smaller than the device region 102. In other embodiments, the through-hole 120 may have an opening size greater than the device region 102. The opening of the through-hole 120 may comprise various shapes, such as a circular, rectangular, elliptic, fan, or polygon shape.

As shown in FIG. 1H, a covering tape 122 may be optionally disposed on a surface of the substrate 108, and it may cover the through-hole 120. The covering tape 122 may facilitate subsequent processes and may protect the device region 102 from being contaminated or damaged. Then, a conductive bump 124 may be formed by performing a bumping process in the openings of the protective layer 118. The material of the conductive bump 124 may be (but is not limited to) tin, lead, copper, gold, nickel, or a combination thereof.

As shown in FIG. 1I, a dicing process may be optionally performed along at least one predetermined scribe line SC of the substrate 100 to form a plurality of separated chip packages. In an embodiment, the covering tape 122 may be optionally removed, as shown in FIG. 1J.

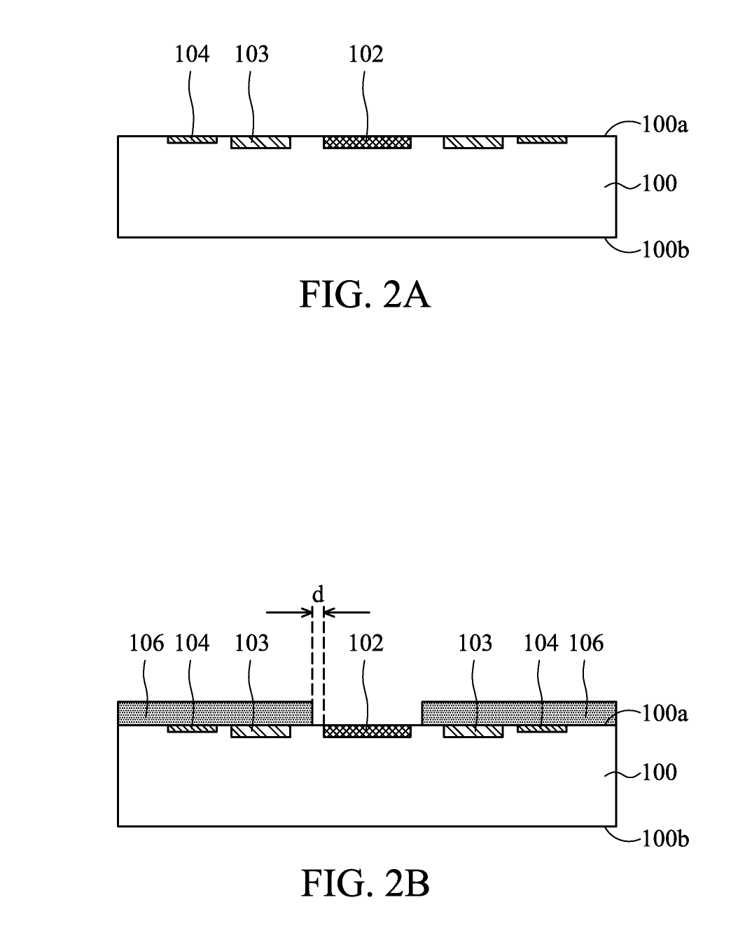

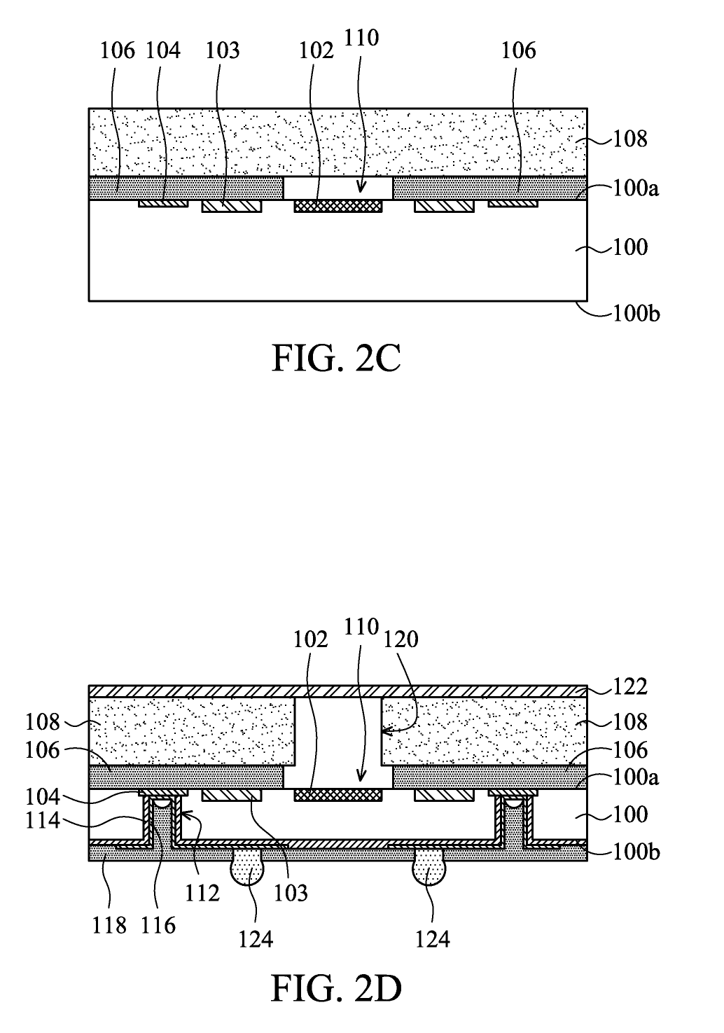

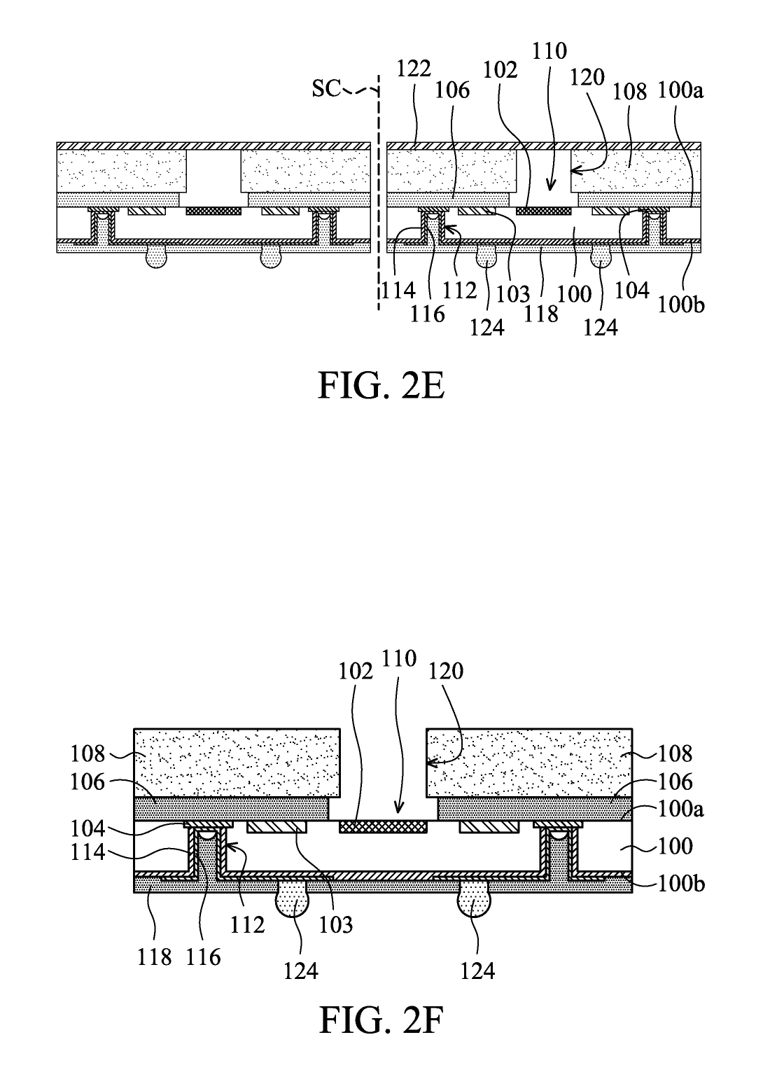

FIGS. 2A-2F show cross-sectional views of the formation of a chip package according to an embodiment of the present invention, in which same or similar reference numbers may be used to refer to same or similar devices. In addition, same or similar devices may use same or similar materials and/or processes.

As shown in FIG. 2A, a substrate 100 having a surface 100a and a surface 100b is provided. A device region 102 may be formed in the substrate 100. The device region 102 may include, but is not limited to, a temperature sensing device, a moisture sensing device, a pressure sensing device, or a combination thereof formed therein. The devices in the device region 102 may electrically connect to a conducting pad structure 104 on the substrate 100 via an interconnection (not shown). In an embodiment, a photo-sensitive region 103 is disposed at the surface 100a of the substrate 100 and between the conducting pad structure 104 and the device region 102. In an embodiment, the photo-sensitive region 103 should be prevented from being illuminated by light (such as visible light or infrared) so as to keep the device region 102 working normally.

Then, as shown in FIG. 2B, a spacer layer 106 may be formed on the surface 100a of the substrate 100. In an embodiment, the spacer layer 106 may have a gap d with an edge of the device region 102.

As shown in FIG. 2C, a substrate 108 may be then formed on the spacer layer 106. A cavity 110 may be created and surrounded by the substrate 108, the spacer layer 106 and the substrate 100 on the device region 102. The cavity 110 may have an area greater than that of the device region 102. In an embodiment, a surface of the device region 102 may be exposed to the cavity 110. The substrate 108 may preferably be formed of an opaque material to prevent the photo-sensitive region 103 from being illuminated.

Then, a structure shown in FIG. 2D is formed by performing processes similar to the processes described in FIGS. 1D-1H. In an embodiment, a sidewall of the through-hole 120 is not coplanar with an edge of the spacer layer 106 nearest to the sidewall of the through-hole 120. The opening size of the through-hole 120 may be less than that of the cavity 110. In addition, in another embodiment, the spacer layer 106 has no gap d with the device region 102. However, when an etching process to the substrate 108 for the formation of the through-hole 120, a portion of the spacer layer 106 may be removed due to the etching process. In this case, the sidewall of the spacer layer 106 nearest to the through-hole 120 would not coplanar with the sidewall of the through-hole 120.

As shown in FIG. 2E, a dicing process may be optionally performed along at least one predetermined scribe line SC of the substrate 100 for forming a plurality of separated chip packages. In an optional embodiment, the covering tape 122 may be removed, as shown in FIG. 2F.

In addition, in the above embodiments, the spacer layer 106 may be formed on the substrate 100 and then bonded to the substrate 100. However, the embodiments of the present invention are not limited to thereto. In other embodiments, the spacer layer 106 may be formed on the substrate 108 and then bonded to the surface 100a of the substrate 100. In this case, a cavity 110 may be created and surrounded by the substrate 100, the spacer layer 106 and the substrate 108 on the device region 102. Then, the processes described in FIG. 1 or FIG. 2 may be used to continue the packaging processes to form a chip package.

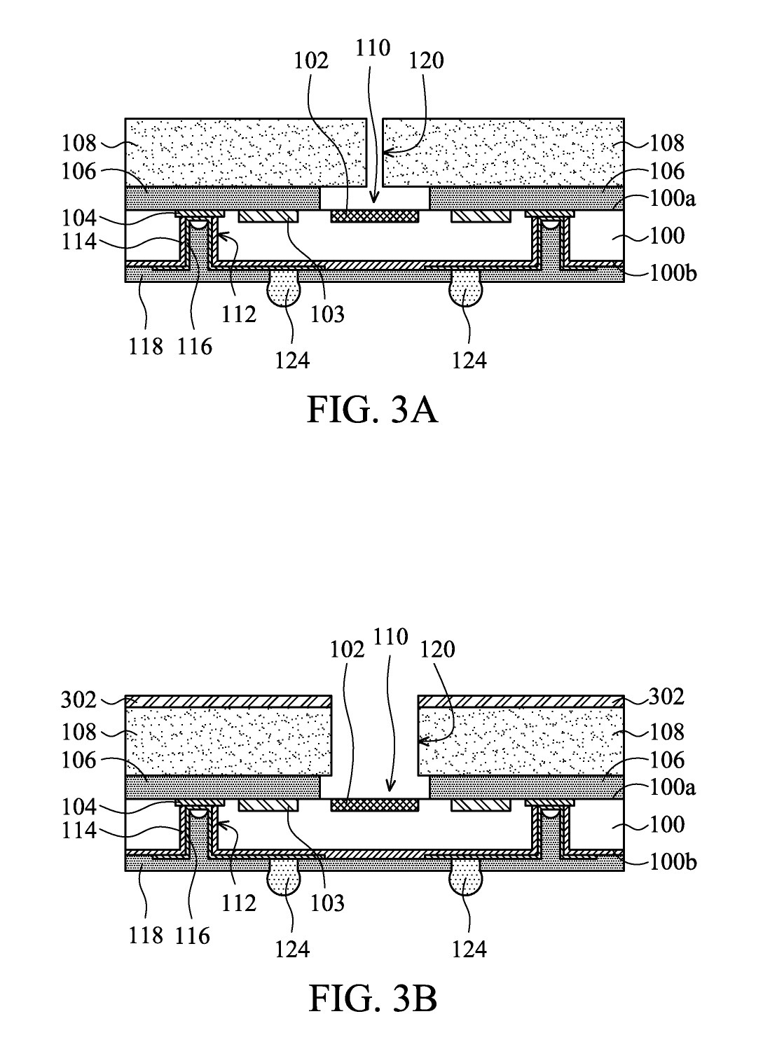

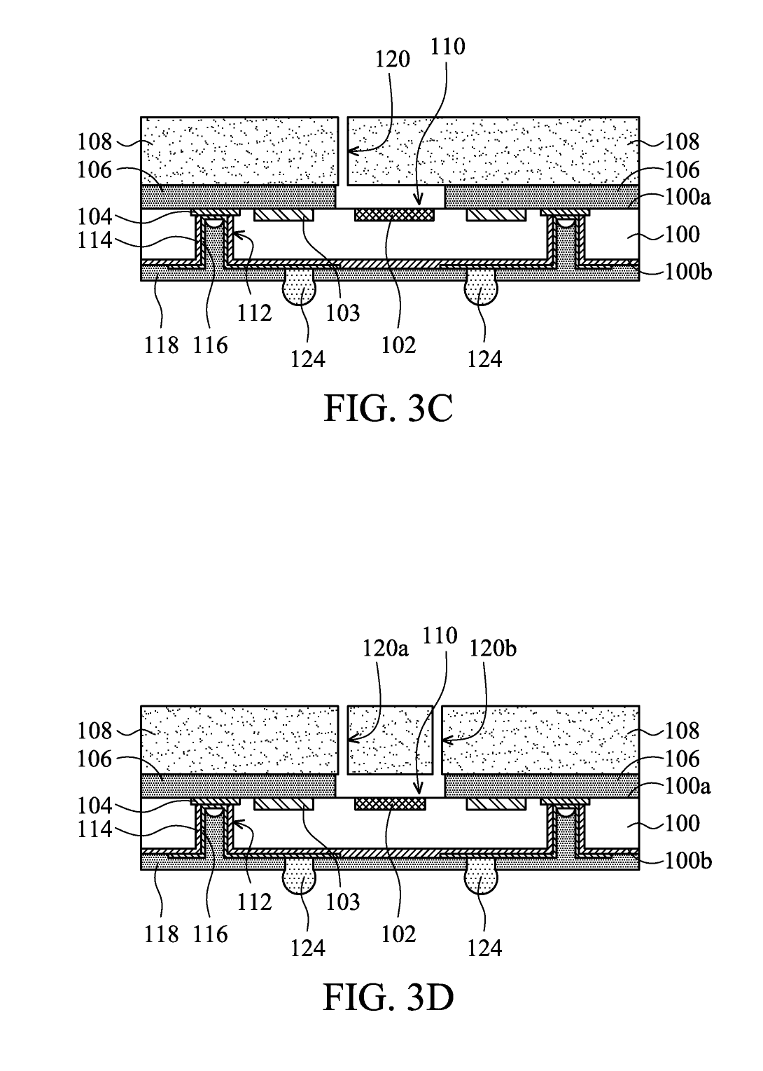

FIGS. 3A-3D show cross-sectional views of chip packages according to embodiments of the present invention, respectively, in which same or similar reference numbers are used to refer to same or similar devices.

As shown in FIG. 3A, in an embodiment, the through-hole 120 may have an opening size less than the cavity 110. The through-hole 120 may directly expose the device region 102.

As shown in FIG. 3B, in an embodiment, a light-shielding layer 302 may be disposed on a surface of the substrate 108, and it may cover the photo-sensitive region 103.

As shown in FIG. 3C, in an embodiment, the through-hole 120 may only connect to the cavity 110, and does not directly expose the device region 102. That is, the projection of the through-hole 120 on the surface 100a of the substrate 100 does not overlap the device region 102.

As shown in FIG. 3D, in an embodiment, a plurality of through-holes connected to the cavity 110, such as the through-hole 120a and the through-hole 120b, may be formed in the substrate 108. The through-holes 120a and 120b may not directly expose the device region 102. Alternatively, one of the through-holes 120a and 120b may directly expose the device region 102.

In the embodiments of the present invention, the chip package may have a significantly reduced size and can be fabricated in mass production. In addition, the fabrication cost and time may be reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a substrate having a first surface and a second surface;
a device region located in the substrate;
a conducting pad structure disposed on the substrate and electrically connected to the device region;
a spacer layer disposed on the first surface of the substrate;
a second substrate disposed on the spacer layer, wherein a cavity is created and surrounded by the second substrate, the spacer layer and the substrate on the device region; and
a through-hole extending from a surface of the second substrate towards the substrate, wherein the through-hole connects to the cavity.

2. The chip package as claimed in claim 1, wherein the device region comprises a temperature sensing device, a moisture sensing device, a pressure sensing device or a combination thereof.

3. The chip package as claimed in claim 1, further comprising a photo-sensitive region disposed on the first surface of the substrate, wherein the photo-sensitive region is located between the conducting pad structure and the device region.

4. The chip package as claimed in claim 1, further comprising:
a hole extending from the second surface of the substrate towards the conducting pad structure;
a trace layer disposed on the second surface of the substrate and extending into the hole for electrically connection with the conducting pad structure; and
an insulating layer disposed between the trace layer and the substrate.

5. The chip package as claimed in claim 1, further comprising:
a protective layer disposed on the second surface of the substrate and exposing an opening of the trace layer; and
a conductive bump disposed in the opening and electrically contact to the trace layer.

6. The chip package as claimed in claim 1, wherein the through-hole directly exposes the device region.

7. The chip package as claimed in claim 1, wherein the through-hole does not directly expose the device region.

8. The chip package as claimed in claim 1, further comprising a second through-hole extending from a surface of the substrate towards the substrate, wherein the second through-hole connects to the cavity.

9. The chip package as claimed in claim 1, further comprising a covering tape disposed on the surface of the second substrate and covering the through-hole.

10. The chip package as claimed in claim 1, wherein the second substrate comprises a semiconductor substrate, a metal substrate, a polymer substrate, a ceramic substrate or a combination thereof.

11. The chip package as claimed in claim 1, wherein the spacer layer directly contacts with the second substrate.

12. The chip package as claimed in claim 1, wherein a sidewall of the spacer layer nearest to the through-hole is not coplanar with a sidewall of the through-hole.

13. The chip package as claimed in claim 1, wherein a sidewall of the spacer layer is substantially coplanar with a sidewall of the through-hole.

14. The chip package as claimed in claim 1, wherein the spacer layer contacts with none of adhesion glue.

15. The chip package as claimed in claim 1, further comprising a light-shielding layer disposed on the surface of the second substrate.

16. A method for forming a chip package, comprising:
providing a substrate having a first surface and a second surface, wherein the substrate comprises a device region formed therein and a conducting pad structure disposed on the substrate and electrically connected to the device region;
forming a spacer layer on the first surface of the substrate;
forming a second substrate on the spacer layer, wherein a cavity is created and surrounded by the second substrate, the spacer layer and the substrate on the device region; and
removing a portion of the second substrate from a surface of the second substrate for forming a through-hole extending towards the substrate, wherein the through-hole connects to the cavity.

17. The method for forming a chip package as claimed in claim 16, further comprising:
removing the portion of the substrate from the second surface of the substrate for forming a hole extending towards the conducting pad structure;
forming an insulating layer on the second surface of the substrate and the sidewalls of the hole; and
forming a trace layer on the insulating layer, wherein the trace layer extends into the hole and electrically connects to the conducting pad structure.

18. The method for forming a chip package as claimed in claim 17, further comprising thinning the surface of the substrate from the second surface of the substrate before the forming the hole.

19. The method for forming a chip package as claimed in claim 16, further comprising disposing a covering tape on the surface of the second substrate, wherein the covering tape covers the through-hole.

20. The method for forming a chip package as claimed in claim 16, further comprising performing a dicing process along at least one scribe line of the substrate for forming a plurality of separated chip packages.

21. A method for forming a chip package, comprising:
providing a substrate having a first surface and a second surface, wherein the substrate comprises a device formed therein and a conducting pad structure disposed on the substrate and electrically connected to the device region;
providing a second substrate;
forming a spacer layer on the second substrate;
bonding the spacer layer to the first surface of the substrate, wherein a cavity is created and surrounded by the second substrate, the spacer layer and the substrate on the device region; and
removing a portion of the second substrate from a surface of the second substrate for forming a through-hole extending towards the substrate, wherein the through-hole connects to the cavity.
